(19) United States
(12) Patent Application Publication
(10) Pub. No.: US 2010/0006844 A1
(43) Pub. Date: Jan. 14, 2010

(54) THIN-FILM TRANSISTOR ARRAY PANEL AND METHOD OF FABRICATING THE SAME

(75) Inventors: Woong-Kwon KIM, Cheonan-si (KR); Jun-Ho SONG, Seongnam-si (KR); Joo-Han KIM, Yongin-si (KR); In-Woo KIM, Suwon-si (KR); Ho-Jun LEE, Anyang-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/464,452

(22) Filed: May 12, 2009

(30) Foreign Application Priority Data
Jul. 14, 2008 (KR) 10-2008-0068237

(51) Int. Cl. H01L 33/00; H01L 21/336

(52) U.S. Cl. 257/59; 438/34; 257/E33.053; 257/E21.412

(57) ABSTRACT

A thin-film transistor (“TFT”) array and a method of fabricating the TFT array panel include: an insulating substrate; a gate line and a data line which are insulated from each other on the insulating substrate and are arranged in a lattice; common wiring extended parallel to the gate line on the insulating substrate; a gate insulating film disposed on the gate line and the common wiring; a semiconductor layer disposed on the gate insulating film; contact holes which penetrate through the gate insulating film and the semiconductor layer disposed on the common wiring; a plurality of common electrodes connected to the common wiring by the contact holes and arranged parallel to each other; and a plurality of pixel electrodes arranged parallel to the plurality of common electrodes.

This application claims priority to Korean Patent Application No. 10-2008-0068237, filed on Jul. 14, 2008, and all the benefits accruing therefrom under 35 U.S.C. §119, the contents of which in its entirety are herein incorporated by reference.

### BACKGROUND OF THE INVENTION

1. Field of the Invention

The present invention relates to a thin-film transistor (“TFT”) array panel and a method of fabricating the same, and more particularly, to a TFT array panel which is structured to maximize processing yields by reducing the number of mask processes required and streamlining the entire fabrication process and a method of fabricating the TFT array panel.

2. Description of the Related Art

As modern society becomes more dependent on sophisticated information and communication technology, the market needs for larger and thinner displays are growing. In particular, since conventional cathode ray tubes (“CRTs”) have failed to fully satisfy these market needs, the demand for flat panel displays (“FPDs”), such as plasma display panels (“PDPs”), plasma address liquid crystal display panels (“PALCs”), liquid crystal displays (“LCDs”), and organic light emitting diodes (“OLEDs”), is ever increasing. Since displays have clear image quality and can be made lighter and thinner, they are widely used in various electronic devices.

LCDs are one of the most widely used FPDs. An LCD includes two display panels, on which electrodes are formed, and a liquid crystal layer interposed between the two display panels. The LCD rearranges liquid molecules of the liquid crystal layer by applying voltages to the electrodes and thus controls the amount of light that passes through the liquid crystal layer disposed between the electrodes. The LCD displays a desired image in this manner.

Each display panel is formed by patterning a plurality of thin-film patterns on an insulating substrate. Thin-film patterns are generally patterned by a photolithography process which is accompanied by processes including coating photoresist, mask alignment, exposure, baking, developing, and washing. Each process affects the total processing time and product cost. Therefore, if the number of processes is reduced, the total product cost can be reduced. In particular, it is desirable to reduce the number of mask processes in order to reduce the number of processes.

### BRIEF SUMMARY OF THE INVENTION

Aspects, advantages and features of the present invention provide a thin-film transistor (“TFT”) array panel and method of fabricating the TFT array panel which is structured to maximize processing yields by reducing the number of mask processes required and streamlining the entire fabrication process and a method of fabricating the TFT array panel.

However, aspects, advantages and features of the present invention are not restricted to the one set forth herein. The above and other aspects, advantages and features of the present invention will become more apparent to one of ordinary skill in the art to which the present invention pertains by referencing the detailed description of the present invention given below.

According to an exemplary embodiment of the present invention, there is provided a TFT array panel including: an insulating substrate; a gate line and a data line which are insulated from each other on the insulating substrate and are arranged in a lattice; common wiring extended parallel to the gate line on the insulating substrate; a gate insulating film disposed on the gate line and the common wiring; a semiconductor layer disposed on the gate insulating film; contact holes which penetrate through the gate insulating film and the semiconductor layer formed on the common wiring; a plurality of common electrodes connected to the common wiring by the contact holes and arranged parallel to each other; and a plurality of pixel electrodes arranged parallel to the plurality of common electrodes.

The plurality of common electrodes and the plurality of pixel electrodes maybe arranged in an alternating fashion.

The panel may further include: a TFT which includes a gate electrode connected to the gate line, a source electrode connected to the data line and a drain electrode connected to the pixel electrodes; and a first connection electrode which connects the pixel electrodes to the drain electrode.

The panel may further include: a storage line extended parallel to the gate line; and a storage electrode connected to the storage line and which overlaps at least one of the first connection electrode and the plurality of pixel electrodes.

The panel may further include a second connection electrode which connects the plurality of common electrodes to the storage line.

At least part of the second connection electrode may not overlap the gate insulating film and the semiconductor layer.

The panel may further include a shield electrode interposed between the plurality of pixel electrodes and the data line, arranged parallel to the plurality of pixel electrodes, and connected to at least one of the common wiring and the storage line.

The panel may further include a second connection electrode which connects the plurality of common electrodes to the storage line, wherein the shield electrode is connected to at least one of the plurality of common electrodes and the storage line by the second connection electrode.

The plurality of common electrodes and the plurality of pixel electrodes may at least partially overlap the common wiring and the storage line.

The panel may further include: a TFT which includes a gate electrode connected to the gate line, a source electrode connected to the data line and a drain electrode connected to the plurality of pixel electrodes; and a first connection electrode which connects the plurality of pixel electrodes to the drain electrode, wherein the common wiring overlaps at least one of the first connection electrode and the plurality of pixel electrodes.

The panel may further include a first passivation layer disposed on regions of the insulating substrate and the gate insulating film that do not overlap the data line, the plurality of common electrodes and the plurality of pixel electrodes.

The panel may further include a second passivation layer disposed on the data line, the plurality of common electrodes, the plurality of pixel electrodes, and the first passivation layer.

According to another exemplary embodiment of the present invention, there is provided a method of fabricating a TFT array panel. The method includes: disposing a gate line and common wiring, which extends parallel to the gate line, on an insulating substrate; disposing a gate insulating film and a semiconductor layer on the gate line and the common wiring; forming contact holes which penetrate through the gate insulating film and the semiconductor layer disposed on the common wiring; and disposing a plurality of common electrodes which are connected to the common wiring by the contact holes and are arranged parallel to each other, a plurality of pixel electrodes which are arranged parallel to the plurality of common electrodes, and a data line which crosses the gate line.

In disposing of the plurality of common electrodes, the plurality of pixel electrodes and the data line, an etching process may be performed using a photoresist pattern, which is disposed on a data line formation region, a common electrode formation region and a pixel electrode formation region, as an etching mask.

The disposing the plurality of common electrodes, the plurality of pixel electrodes and the data line may include depositing a conductive material for disposing the data line on the insulating substrate and wet-etching the deposited conductive material.

The method may further include disposing a first passivation layer on regions of the insulating substrate and the gate insulating film which do not overlap the plurality of common electrodes, the plurality of pixel electrodes and the data line.

The disposing the first passivation layer may include depositing a material for disposing the first passivation layer on the insulating substrate having the photoresist pattern and removing the photoresist pattern by using a lift-off process.

The method may further include disposing a second passivation layer on the plurality of common electrodes, the plurality of pixel electrodes, the data line and the first passivation layer.

The gate line may further include a gate pad at an end thereof, and the method may further include etching the second passivation layer to expose the gate pad.

The method may further include: disposing a storage line which extends parallel to the gate line; and disposing a storage electrode which is connected to the storage line and overlaps the plurality of pixel electrodes.

The method may further include forming a connection electrode which connects the plurality of common electrodes to the storage line.

At least part of the connection electrode may not overlap the gate insulating film and the semiconductor layer.

The method may further include disposing a shield electrode which is interposed between the data line and at least one of the plurality of pixel electrodes and the plurality of common electrodes, arranged parallel to the plurality of pixel electrodes, and connected to the connection electrode.

The method may further include disposing a shield electrode which is interposed between the data line and at least one of the plurality of pixel electrodes and the plurality of common electrodes, arranged parallel to the plurality of pixel electrodes, and connected to at least one of the plurality of common electrodes and the plurality of pixel electrodes.

### BRIEF DESCRIPTION OF THE DRAWINGS

The above and other aspects, advantages and features of the present invention will become more apparent by describing in further detail exemplary embodiments thereof with reference to the attached drawings, in which:

FIG. 1 is a plan view of an exemplary embodiment of a thin-film transistor (“TFT”) array panel according to the present invention;

FIG. 2A is a cross-sectional view of the TFT array panel taken along line Ia-Ia′ of FIG. 1;

FIG. 2B is a cross-sectional view of the TFT array panel taken along line IIb-IIb′ of FIG. 1;

FIGS. 3A and 3B are plan views for sequentially explaining processes included in an exemplary embodiment of a method of fabricating the TFT array panel of FIG. 1 according to the present invention;

FIGS. 4A through 11B are cross-sectional views for sequentially explaining the processes included in the exemplary embodiment of the method of fabricating the TFT array panel of FIG. 1 according to the present invention;

FIG. 12 is a plan view of another exemplary embodiment of a TFT array panel according to the present invention; and

FIGS. 13A and 13B are cross-sectional views for sequentially explaining processes included in another exemplary embodiment of a method of fabricating a TFT array panel according to the present invention.

### DETAILED DESCRIPTION OF THE INVENTION

Aspects, advantages and features of the present invention and methods of accomplishing the same may be understood more readily by reference to the following detailed description of exemplary embodiments and the accompanying drawings. The present invention may, however, be embodied in many different forms and should not be construed as being limited to the exemplary embodiments set forth herein. Rather, these exemplary embodiments are provided so that this disclosure will be thorough and complete and will fully convey the concept of the invention to those skilled in the art, and the present invention will only be defined by the appended claims. Like reference numerals refer to like elements throughout the specification.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terms “the”, “a”, and “an” do not denote a limitation of quantity, but rather denote the presence of at least one of the referenced item.

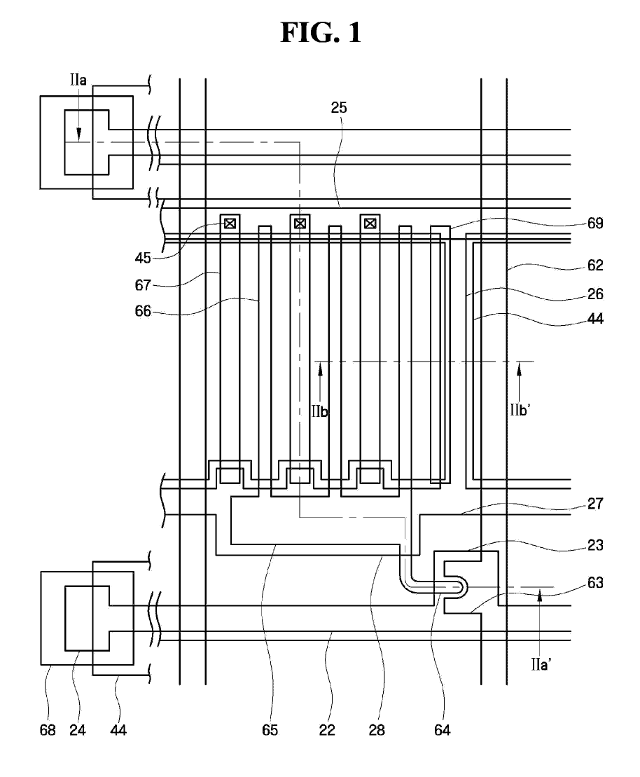

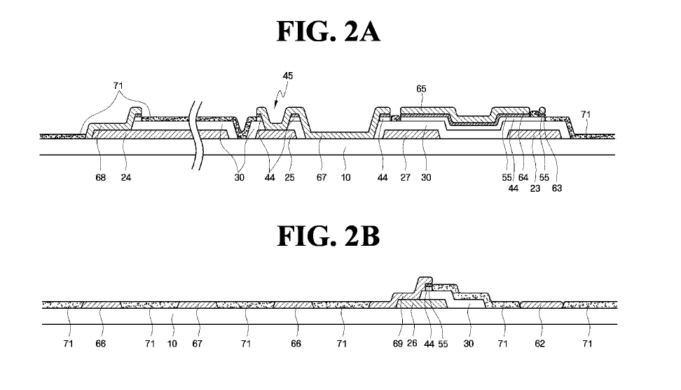

Hereinafter, an exemplary embodiment of a thin-film transistor (“TFT”) array panel according to the present invention will be described in further detail with reference to FIGS. 1 through 2B. FIG. 1 is a plan view of an exemplary embodiment of a TFT array panel according to the present invention. FIG. 2A is a cross-sectional view of the TFT array panel taken along line IIa-IIa′ of FIG. 1. FIG. 2B is a cross-sectional view of the TFT array panel taken along line IIb-IIb′ of FIG. 1.

Referring to FIGS. 1 through 2B, a gate line 22, a gate pad 24 and a gate electrode 23 are disposed on an insulating substrate 10, which is made of transparent glass or plastic. The gate line 22 generally extends in a horizontal direction, as illustrated in FIG. 1, and delivers a gate signal. A plurality of gate lines like the gate line 22 are disposed on the insulating substrate 10 and are arranged in parallel to each other in the same direction. The gate pad 24 having a large width is disposed at an end of the gate line 22.

The gate electrode 23 may be formed by a portion protruding from the gate line 22. A plurality of gate electrodes like the gate electrode 23 may be connected to the gate line 22. The gate line 22, the gate pad 24 and the gate electrode 24 will collectively be referred to as “gate wiring”.

A storage line 27 also extends on the insulating substrate 10 across a pixel region. The storage line 27 extends substantially parallel to the gate line 22 and is connected to a storage electrode 28. The storage electrode 28 may be formed by extending a portion of the storage line 27. The storage electrode 28 overlaps at least one of a first connection electrode 65 and pixel electrodes 66 to form a storage capacitor which enhances the charge storage capability of a pixel.

In the present exemplary embodiment, the storage line 27 extends parallel to the gate line 22 and overlaps at least one of the first connection electrode 65 and the pixel electrodes 66. However, the present invention is not limited thereto. The storage line 27 and the storage electrode 28 may have various shapes and may be disposed at various locations. If sufficient storage capacitance is generated by the overlapping of the pixel electrodes 66 and common wiring 25, the storage line 27 and the storage electrode 28 may not be formed. The storage line 27 and the storage electrode 28 will be collectively referred to as “storage wiring”.

The common wiring 25 extends substantially parallel to the gate line 22 on the insulating substrate 10. The common wiring 25 is connected to common electrodes 67 and provides a common voltage to the common electrodes 67. The common wiring 25 may be connected to the storage wiring (i.e., the storage line 27 and the storage electrode 28) by a second connection electrode 26. That is, the same common voltage may be applied to the common wiring 25 and the storage wiring. However, connecting the common wiring 25 and the storage wiring by using the second connection electrode 26 and applying the same common voltage to the common wiring 25 and the storage wiring is a mere example, and is not limited thereto. That is, the common wiring 25 and the storage wiring may be separated from each other, and different voltages may be applied to the common wiring 25 and the storage wiring, respectively.

The second connection electrode 26 may extend substantially parallel to a data line 62. The second connection electrode 26 may be separated from the data line 62 by a predetermined gap. However, the present invention is not limited thereto. That is, at least a portion of the second connection electrode 26 may overlap the data line 62 in order to increase an aperture ratio.

The pixel electrodes 66 and the common electrodes 67 may be disposed between the common wiring 25 and the storage wiring (i.e., the storage line 27 and the storage electrode 28) to form a pixel region.

Each of the gate wiring, the storage wiring, and the common wiring 25 may be made of aluminum (Al)-based metal such as Al or Al alloys, silver (Ag)-based metal such as Ag or Ag alloys, copper (Cu)-based metal such as Cu or Cu alloys, molybdenum (Mo)-based metal such as Mo or Mo alloys, chrome (Cr), titanium (Ti), or tantalum (Ta).

In addition, each of the gate wiring, the storage wiring and the common wiring 25 may have a multi-layer structure composed of two conductive layers (not shown) with different physical characteristics. In this case, one of the two conductive layers may be made of metal with low resistivity, such as Al-based metal, Ag-based metal or Cu-based metal, in order to reduce signal delays or voltage drops of the gate wiring, the storage wiring and the common wiring 25. On the other hand, the other one of the conductive layers may be made of a different material, in particular, a material having superior contact characteristics with indium tin oxide (“ITO”) and indium zinc oxide (“IZO”), such as Mo-based metal, Cr, Ti, or Ta. Good examples of the multi-layer structure may include a combination of a Cr lower layer and an Al upper layer or a combination of an Al lower layer and a Mo upper layer. However, the present invention is not limited thereto. Each of the gate wiring, the storage wiring and the common wiring 25 may be made of various metals and conductors.

A gate insulating film 30 is made of, e.g., silicon nitride (SiNx) and is disposed on the gate wiring which excludes the gate pad 24, the storage wiring and the common wiring 25. The gate insulating film 30 insulates the gate wiring, the storage wiring and the common wiring 25 from data wiring which will be described later. That is, in regions where the gate wiring, the storage wiring and the common wiring 25 overlap the data wiring, the gate insulating film 30 is interposed between the gate wiring, the storage wiring and the common wiring 25 and the data wiring.

The gate insulating film 30 may not be formed in a pixel region, which is defined by the common electrodes 67 and the pixel electrodes 66, thereby directly exposing the insulating substrate 10.

A semiconductor layer 44 and an ohmic contact layer 55 are formed on the gate insulating film 30. The semiconductor layer 44 is made of hydrogenated amorphous silicon, and the ohmic contact layer 55 is made of silicide or n+ hydrogenated amorphous silicon which is doped with n-type impurities in high concentration. The semiconductor layer 44 forms a channel region of a TFT. The channel region is formed of the semiconductor layer 44 which overlaps the gate electrode 23. Except for the channel region, the ohmic contact layer 55 has substantially the same pattern as the semiconductor layer 44. In a region where the ohmic contact layer 55 overlaps the gate electrode 23, the ohmic contact layer 55 is divided into two parts with the channel region interposed therebetween. The ohmic contact layer 55 is formed on the semiconductor layer 44.

The data line 62, a source electrode 63, a drain electrode 64 and the first connection electrode 65 are formed on the semiconductor layer 44 and the ohmic contact layer 55. The data line 62 generally extends in a vertical direction and crosses the gate line 22, as illustrated in FIG. 1. A plurality of data lines like the data line 62 and a plurality of gate lines like the gate line 22 are arranged in a lattice to define a plurality of pixels.

Each pixel includes a TFT having the gate electrode 23, the source electrode 63 and the drain electrode 64 as its three terminals. The source electrode 63 may be formed by a protruding portion of the data line 62, and the drain electrode 64 is separated from the source electrode 63 with the channel region interposed therebetween and faces the source electrode 63.

The drain electrode 64 is connected to the pixel electrodes 66 by the first connection electrode 65. The first connection electrode 65 connects respective ends of the pixel electrodes 66 to each other and may extend in the same direction as the gate line 22. The first connection electrode 65 may overlap the storage line 27 and the storage electrode 28 to form a storage capacitor.

The pixel electrodes 66 extend from the first connection electrode 65 to be parallel to the data line 62. The pixel electrodes 66 are formed in each pixel and extend parallel to each other. The pixel electrodes 66 and the common electrodes 67 are alternately arranged with respect to each other to define a pixel region. The pixel electrodes 66 and the common electrodes 67 may be made of opaque metal wiring. Thus, light may pass through regions between the pixel electrodes 66 and the common electrodes 67.

The pixel electrodes 66 and the common electrodes 67 may be shaped like rectangles that extend parallel to the data line 62. In order to increase an aperture ratio of the pixel, the pixel electrodes 66 and the common electrodes 67 may be formed narrower than the data line 62. The ends of the pixel electrodes 66 may partially overlap the common wiring 25, as illustrated in FIG. 1, to prevent the leakage of light.

The common electrodes 67 and the pixel electrodes 66 form an electric field to control liquid crystals and thus adjust transmittance of each pixel. The common electrodes 67 are connected to the common wiring 25 by contact holes 45. That is, an end of each of the common electrodes 67 is connected to the common wiring 25 by one of the contact holes 45, and the other end of each of the common electrodes 67 at least partially overlaps the storage line 27 or the storage electrode 28. When an end of the common wiring 25 partially overlaps the storage wiring or the storage electrode 28, the leakage of light can be prevented.

A shield electrode 69 may be formed between the data line 62 and one of the pixel electrodes 66 or one of the common electrodes 67 which is adjacent to the data line 62. The shield electrode 69 prevents an electric field generated by the data line 62 from affecting a pixel region. The shielding electrode 69 may be connected to at least one of the common wiring 25 and the storage line 27. That is, the same voltage as the voltage that is applied to the common wiring 25 and the storage line 27 may be applied to the shield electrode 69.

The shield electrode 69 may be connected to the second connection electrode 26 which connects the common wiring 25 to the storage line 27. The gate insulating film 30 and the semiconductor layer 44 may at least partially expose the second connection electrode 26. Therefore, the shield electrode 69 may at least partially overlap the second connection electrode 26 which is at least partially exposed by the gate insulating film 30 and the semiconductor layer 44, so that the shield electrode 69 can be connected to the second connection electrode 26.

A gate pad extension portion 68 is formed on the gate pad 24. That is, the gate insulating film 30 and the semiconductor layer 44 on the gate pad 24 are removed to form the gate pad extension portion 68 which is connected to the gate pad 24. The gate pad extension portion 68 may be formed wider than the gate pad 24 so that it can be easily connected to a gate driver integrated circuit (“IC”) (not shown).

The data line 62, the source electrode 63, the drain electrode 64, the first connection electrode 65, the pixel electrodes 66, the common electrodes 67, the second connection electrode 26, and the gate pad extension portion 68 may be made of the same material in the same process. In particular, the drain electrode 64, the first connection electrode 65, and the pixel electrodes 66 may be formed as a single unitary body in the same process. For convenience, the source electrode 63, the drain electrode 64 and the data line 62 will collectively be referred to as the data wiring.

The data wiring may be made of refractory metal such as Cr, Mo-based metal, Ta or Ti. In addition, the data wiring may have a multi-layer structure composed of a lower layer (not shown), which is made of refractory metal, and an upper layer (not shown) which is made of a material with low resistivity and is disposed on the lower layer. The multi-layer structure may be a double-layer structure composed of a combination of a lower layer, which contains a Mo or Ti lower layer and a Cu upper layer or a combination of an Al lower layer and a Mo upper layer. However, the present invention is not limited thereto. The multi-layer structure may be a triple-layer structure composed of Mo—Al—Mo layers.

A first passivation layer 71 is formed in regions excluding regions where the data line 62, the source electrode 63, the drain electrode 64, the first connection electrode 65, the pixel electrodes 66, the common electrodes 67, the second connection electrode 26, and the gate pad extension portion 68 are formed. The first passivation layer 71 may protect the channel region of a TFT and may be formed by using low-temperature chemical vapor deposition (“LTCVD”) and a sputter film in order to protect a photoresist pattern which will be described later. The first passivation layer 71 may be made of for example, silicon oxide (SiOx), silicon oxynitride (SiOxNy), or SiNx.

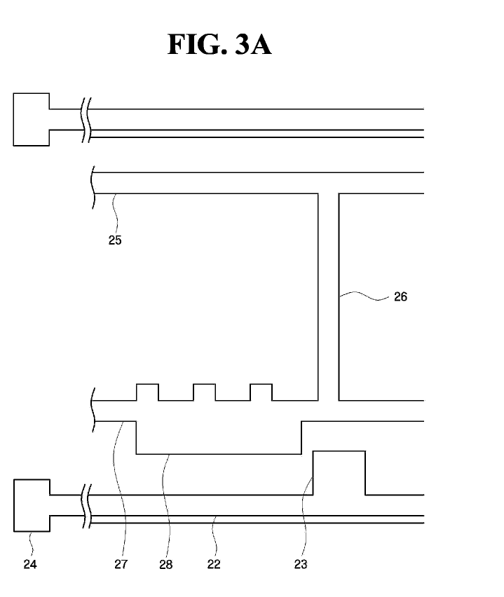

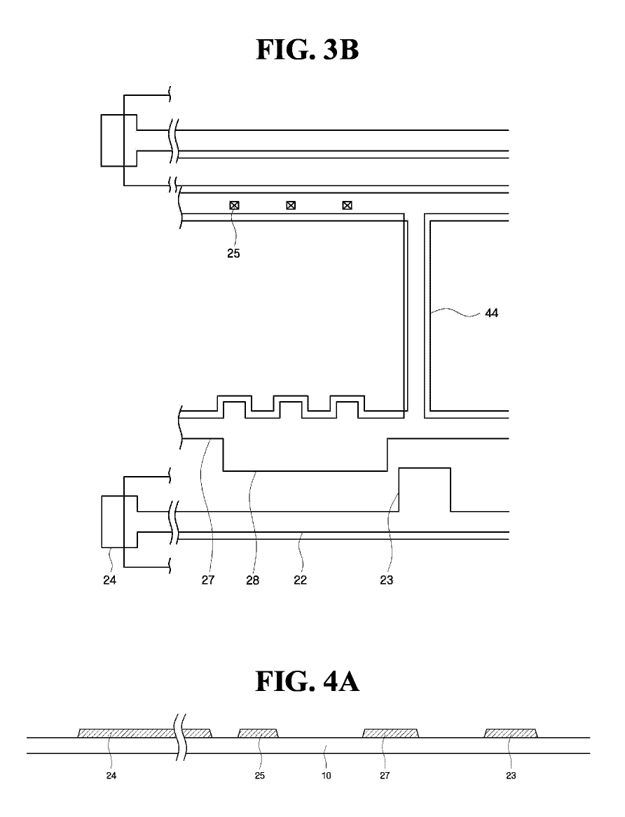

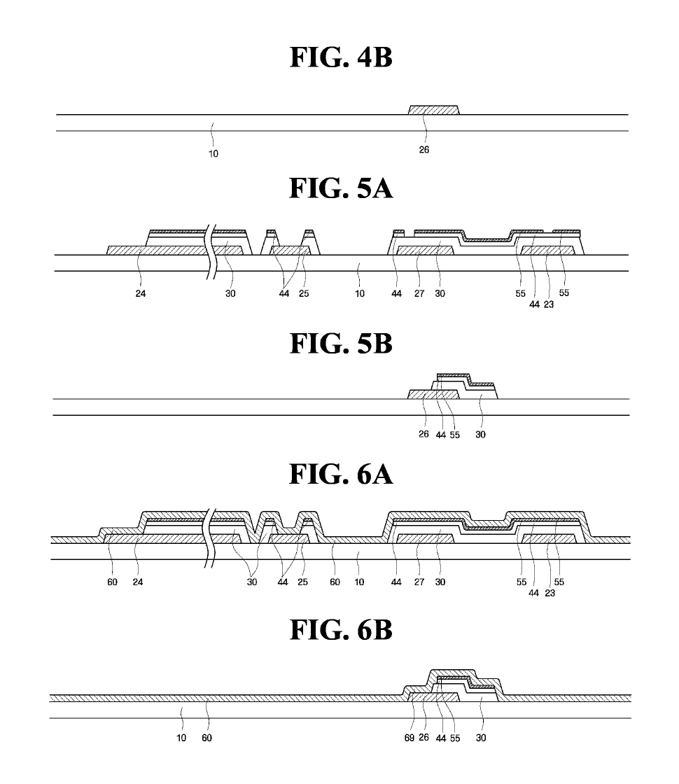

Hereinafter, an exemplary embodiment of a method of fabricating a TFT array panel according to the present invention will be described with reference to FIGS. 3A through 11B. FIGS. 3A and 3B are plan views for sequentially explaining processes included in the exemplary embodiment of the method of fabricating the TFT array panel of FIG. 1 according to the present invention. FIGS. 4A through 11B are cross-sectional views for sequentially explaining the processes included in the exemplary embodiment of the method of fabricating the TFT array panel of FIG. 1 according to the present invention.

Referring to FIGS. 3A, 4A and 4B, the gate wiring (i.e., the gate line 22, the gate electrode 23 and the gate pad 24), the common wiring 25, and the storage wiring (i.e., the storage line 27 and the storage electrode 28) are formed on the insulating substrate 10. Specifically, a gate conductive layer is deposited on the insulating substrate 10 by sputtering, for example, but is not limited thereto. Then, a photolithography process is performed on the gate conductive layer to form the gate line 22, the gate pad 24, the gate electrode 23, the common wiring 25, the storage line 27, and the storage electrode 28.

Referring to FIGS. 3B, 5A and 5B, a gate insulating layer, a first amorphous silicon layer and a second amorphous silicon layer are deposited on the resultant structure of FIGS. 3A, 4A and 4B. The first amorphous silicon layer is made of hydrogenated amorphous silicon, and the second amorphous silicon layer is made of silicide or n+ hydrogenated amorphous silicon which is doped with n-type impurities in high concentration. The gate insulating layer, the first amorphous silicon layer and the second amorphous silicon layer may be deposited by chemical vapor deposition (“CVD”), for example, but is not limited thereto.

Next, the photolithography process is performed on the gate insulating layer, the first amorphous silicon layer, and the second amorphous silicon layer to form the gate insulating film 30, the semiconductor layer 44 and the ohmic contact layer 55. Specifically, the gate insulating layer, the first amorphous silicon layer and the second amorphous silicon layer are sequentially deposited on the insulating substrate 10 to cover the gate wiring, the common wiring 25 and the storage wiring.

The first amorphous silicon layer and the second amorphous silicon layer may be dry-etched, for example, but is not limited thereto. The first amorphous silicon layer may be etched to form the semiconductor layer 44, and the second amorphous silicon layer may be etched to form the ohmic contact layer 55. The semiconductor layer 44 and the ohmic contact layer 55 may be etched simultaneously or separately.

After the first amorphous silicon layer and the second amorphous silicon layer are etched, the gate insulating layer is exposed. Then, the gate insulating layer is etched by using the same etching mask as the etching mask for the first and second amorphous silicon layers. As a result, the gate insulating film 30 is formed.

Referring to FIGS. 6A and 6B, a data conductive layer 60 is deposited on the resultant structure of FIGS. 5A and 5B by sputtering, for example, but is not limited thereto. Specifically, the data conductive layer 60 is deposited on a whole surface of the insulating substrate 10 to cover the gate insulating film 30, the semiconductor layer 44 and the ohmic contact layer 55.

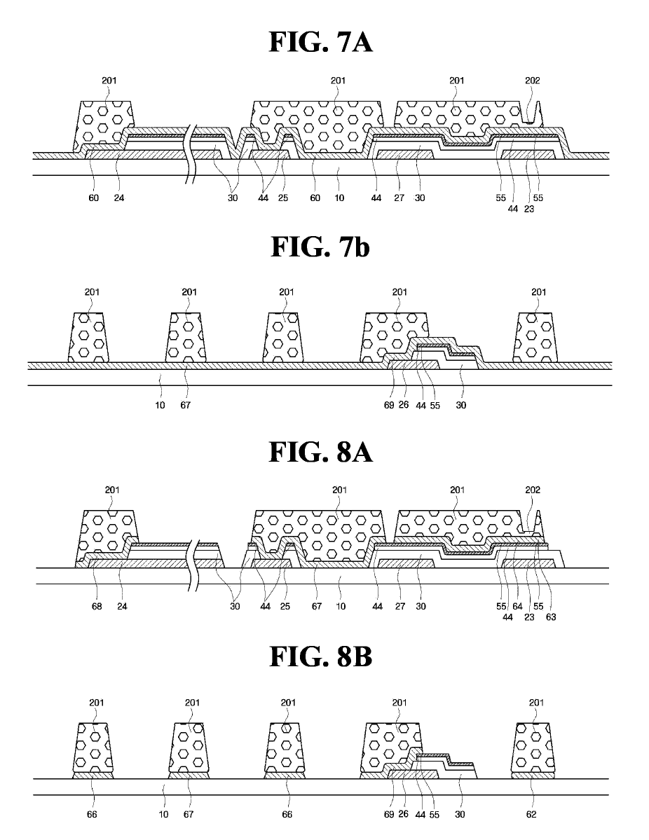

Referring to FIGS. 7A and 7B, the photoresist pattern is disposed on the data conductive layer 60. The photoresist pattern may be divided into a first region 201 and a second region 202. The second region 202 may be thinner than the first region 201, as illustrated.

The first region 201 includes a data line formation region, a common electrode formation region and a pixel electrode formation region shown in FIGS. 2A and 2B. The first region 201 is formed on the data conductive layer 60 from which the data line 62, the source electrode 63, the drain electrode 64, the pixel electrodes 66 and the common electrodes 67 are formed. The second region 202 is formed on the channel region which separates the source electrode 63 from the drain electrode 64.

Since the thicknesses and widths of the first region 201 and the second region 202 of the photoresist pattern will be reduced in subsequent etching and ashing processes, a predetermined margin may be given thereto. In order to form the first region 201 and the second region 202 of the photoresist pattern to have different thicknesses a slit mask or a half-ton mask may be used, for example, but is not limited thereto.

Referring to FIGS. 8A and 8B, an exposed portion of the data conductive layer 60 is etched by using the photosensitive pattern as an etching mask. The etching process of the data conductive layer 60 may vary according to the type and thickness of the data conductive layer 60. For example, the data conductive layer 60 may be wet-etched. As a result of etching the data conductive layer 60 using the photoresist pattern as an etching mask, the data line 62, the source electrode 63, the drain electrode 64, the pixel electrodes 66 and the common electrodes 67 are formed, as illustrated in FIG. 8B.

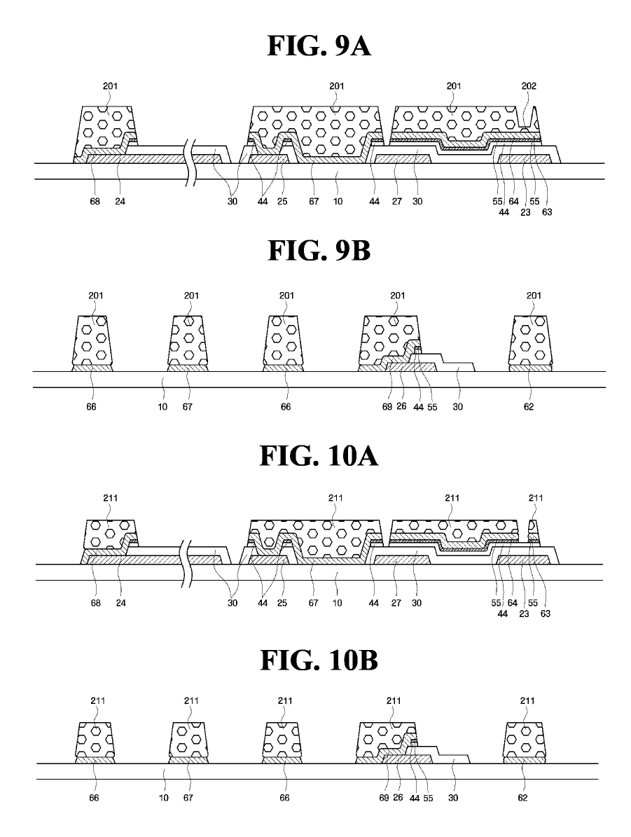

Referring to FIGS. 9A and 9B, the semiconductor layer 44 and the ohmic contact layer 55, which are exposed between the first and second regions 201 and 202 of the photoresist pattern, are removed, except for regions where the semiconductor layer 44 and the ohmic contact layer 55 overlap the data line 62, the source electrode 63, the drain electrode 64, the pixel electrodes 66 and the common electrode 67. When exposed to light, the semiconductor layer 44 and the ohmic contact layer 55 tend to become conductive.

If the semiconductor layer 44 and the ohmic contact layer 55 become conductive when exposed to light from an external source or a backlight assembly, the data line 62, the source electrode 63, the drain electrode 64, the pixel electrodes 66 and the common electrodes 76 may be electrically connected to each other. To prevent this problem, the semiconductor layer 44 and the ohmic contact layer 55 may be dry-etched using the photoresist pattern as an etching mask.

The semiconductor layer 44 and the ohmic contact layer 55 in regions excluding the regions where the semiconductor layer 44 and the ohmic contact layer 55 overlap the data line 62, the source electrode 63, the drain electrode 64, the pixel electrodes 66 and the common electrodes 67 are etched. Here, the semiconductor layer 44 and the ohmic contact layer 55 in the channel region between the source electrode 63 and the drain electrode 64 are not removed. The photoresist pattern is disposed on the channel region, and the photoresist pattern formed on the channel region is the second region 202 which is thinner than the first region 201.

Referring to FIGS. 10A and 10B, part of the photoresist pattern is removed to form a channel. Specifically, the second region 202 formed on the channel region is removed to expose the ohmic contact layer 55 in the channel region. Here, part of the photoresist pattern 201 and 202 may be removed by an ashing process using O₂. When the ashing process is performed on a whole surface of the photoresist pattern, the second region 202, which is thinner than the first region 201, is completely removed, and the thickness and size of the first region 201 are reduced.

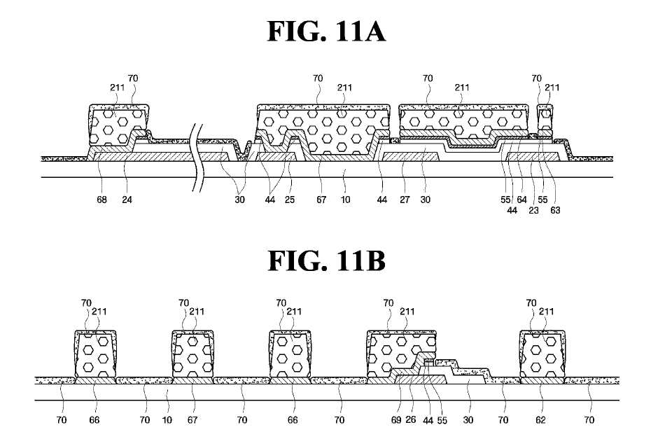

Next, the exposed ohmic contact layer 55 is removed by using the downsized photoresist pattern (indicated by reference numeral 211 in FIGS. 10A through 11B as photoresist pattern 201 having a reduced thickness) as an etching mask. Here, only the exposed ohmic contact layer 55 is removed to expose the semiconductor layer 44. The exposed semiconductor layer 44 forms the channel of a TFT.

Referring to FIGS. 11A and 11B, a material 70 for forming a passivation layer is deposited on a whole surface of the resultant structure of FIGS. 10A and 10B. The material 70 may be, for example, SiOx, SiOxNy, or SiNx and may be deposited by LTCVD or sputtering in order to protect the photoresist pattern. Here, a portion of the material 70 is deposited on the downsized photoresist pattern 211, and the other portion of the material 70 is deposited immediately on regions of the resultant structure which were exposed by the removal of the photoresist pattern.

Referring back to FIGS. 2A and 2B, the downsized photoresist pattern 211 and the material 70 disposed on the downsized photoresist pattern 211 are removed by a lift-off process. Specifically, a photoresist stripper, which contains an amine-based material or a glycol-based material, is sprayed on the downsized photoresist pattern 211 or the downsized photoresist pattern is dipped into the photoresist tripper. Then, the photoresist stripper melts the downsized photoresist pattern 211 and thus exfoliates the downsized photoresist pattern from the data line 62, the source electrode 63, the drain electrode 64, the pixel electrodes 66 and the common electrodes 67 while also removing the material 70 disposed on the downsized photoresist pattern 211. The removal rate of the downsized photoresist pattern 211 and the material 70 disposed on the downsized photoresist pattern 211 may be determined by the contact time and the contact area of the downsized photoresist pattern 211 and the photoresist stripper.

As a result of removing the downsized photoresist pattern 211 and the material 70, a first passivation layer 71 is formed to cover regions excluding the gate pad 24, the data line 62, the source electrode 63, the drain electrode 64, the pixel electrodes 66 and the common electrodes 67. Here, the first passivation layer 71 may expose a data pad (not shown) formed at an end of the data line 62.

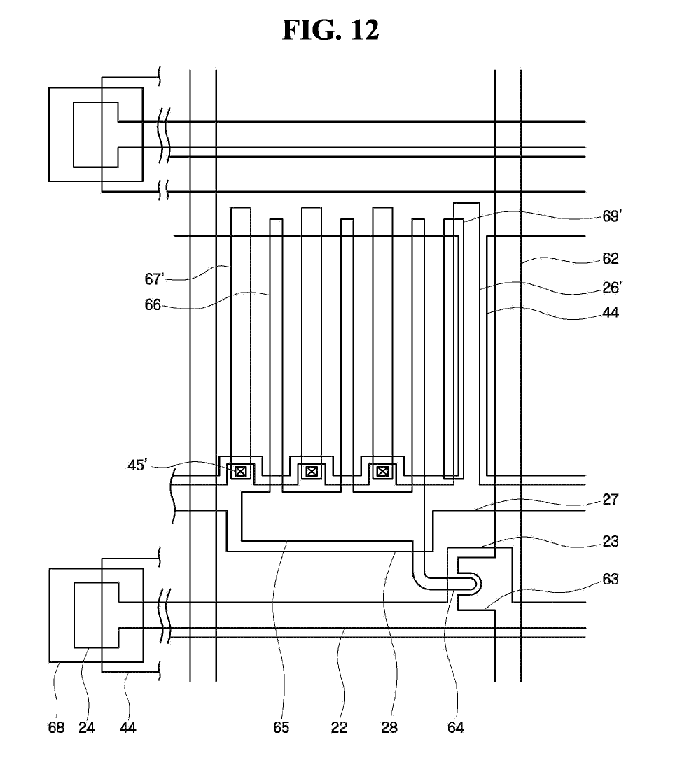

Hereinafter, another exemplary embodiment of a TFT array panel according to the present invention will be described in further detail with reference to FIG. 12. FIG. 12 is a plan view of another exemplary embodiment of a TFT array panel according to the present invention. For simplicity, elements substantially identical to those of the previous embodiment are indicated by like reference numerals, and thus their description will be omitted.

In the TFT array panel according to the present embodiment, common electrodes 67′ are connected to a storage line 27. Specifically, the same common voltage may be applied to the common electrodes 67′ and storage wiring (i.e., the storage line 27 and a storage electrode 28). Thus, the common electrodes 67′ and the storage wiring may be connected to each other. In this case, since separate wiring for applying a common voltage to the common electrodes 67′ can be removed, an aperture ratio of a pixel can be increased.

The storage wiring may also function as common wiring. Thus, there is no need to form the common wiring in addition to the storage wiring. In the present embodiment, the storage wiring will be understood as encompassing the common wiring.

The storage wiring to which a common voltage is applied is formed on the same plane as gate wiring and overlaps pixel electrodes 66 and a first connection electrode 65 to form a storage capacitor. Here, the pixel electrodes 66 extend from the first connection electrode 65 and are arranged parallel to each other. The common electrodes 67′ and the pixel electrodes 66 are arranged parallel to each other in an alternating fashion. As described above, the pixel electrodes 66 and the common electrodes 67′ are formed together in the same process. Since bottom surfaces of the pixel electrodes 66 and the common electrodes 67′ directly contact an insulating substrate 10 (see FIG. 2A), the height of the pixel electrodes 66 is equal to the height of the common electrodes 67′. Therefore, a liquid crystal layer is equally affected by the thickness of the pixel electrodes 66 and that of the common electrodes 67′ in a pixel region.

The common electrodes 67′ and the pixel electrodes 66 may partially overlap a gate line 22 of a previous pixel. Since the common electrodes 67′ and the pixel electrodes 66 are opaque electrodes, the leakage of light around the gate line 22 can be prevented by eliminating the gap between the gate line 22 and the common and pixel electrodes 67′ and 66.

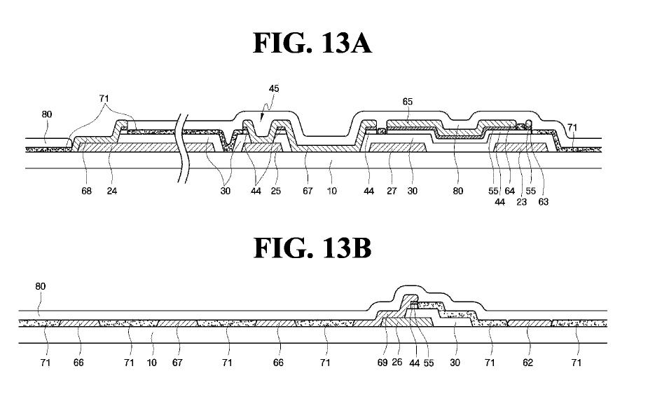

Hereinafter, another exemplary embodiment of a method of fabricating a TFT array panel according to the present invention will be described in further detail with reference to FIGS. 2A, 2B, 13A and 13B. FIGS. 13A and 13B are cross-sectional views for sequentially explaining processes included in another exemplary embodiment of the method of fabricating a TFT array panel according to the present invention. For simplicity, elements substantially identical to those of the previous embodiments are indicated by like reference numerals, and thus their description will be omitted.

In the fabrication method according to the present embodiment, a second passivation layer 80 is formed on a structure excluding a gate pad 24 and a data pad (not shown). Specifically, since a data line 62, a source electrode 63, a drain electrode 64, pixel electrodes 66 and common electrodes 67 are exposed, their characteristics may be affected by, for example, a liquid crystal layer. Thus, the data line 62, the source electrode 63, the drain electrode 64, the pixel electrodes 66 and the common electrodes 67 are covered with the second passivation layer 80.

The fabrication method according to the present embodiment includes a new process in addition to the processes included in the fabrication method described above with reference to FIGS. 4A through 11B. That is, a material for forming a second passivation layer is coated on a whole surface of the TFT shown in FIGS. 2A and 2B which is a final structure manufactured by using the fabrication method of FIGS. 4A through 11B. The material may be, for example, SiOx, SiOxNy, or SiNx. In order to protect a first passivation layer 71, the material may be deposited by LTCVD or sputtering.

Referring to FIGS. 13A and 13B, after the material for forming a second passivation layer is coated on the whole surface of the TFT array panel of FIGS. 2A and 2B, it is etched using an etching mask to expose the gate pad 24 and the data pad (not shown). As a result, the second passivation layer 80 is formed. Here, the second passivation layer 80 covers all regions excluding the gate pad 24 and the data pad (not shown).

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A thin-film transistor array panel comprising:
an insulating substrate;
a gate line and a data line which are insulated from each other on the insulating substrate and are arranged in a lattice;
common wiring extended parallel to the gate line on the insulating substrate;
a gate insulating film disposed on the gate line and the common wiring;
a semiconductor layer disposed on the gate insulating film and the common wiring;
contact holes which penetrate through the gate insulating film and the semiconductor layer disposed on the common wiring;
a plurality of common electrodes connected to the common wiring by the contact holes, each of the plurality of common electrodes are arranged parallel to each other; and
a plurality of pixel electrodes arranged parallel to the plurality of common electrodes.

2. The thin-film transistor array panel of claim 1, wherein each of the plurality of common electrodes and each of the plurality of pixel electrodes are arranged in an alternating fashion.

3. The thin-film transistor array panel of claim 1, further comprising:
a thin-film transistor which comprises a gate electrode connected to the gate line, a source electrode connected to the data line, and a drain electrode connected to the pixel electrodes; and
a first connection electrode which connects the pixel electrodes to the drain electrode.

4. The thin-film transistor array panel of claim 3, further comprising:
a storage line extended parallel to the gate line; and
a storage electrode connected to the storage line and which overlaps at least one of the first connection electrode and the plurality of pixel electrodes.

5. The thin-film transistor array panel of claim 4, further comprising a second connection electrode which connects the common electrodes to the storage line.

6. The thin-film transistor array panel of claim 5, wherein at least part of the second connection electrode does not overlap the gate insulating film and the semiconductor layer.

7. The thin-film transistor array panel of claim 1, further comprising a shield electrode interposed between the plurality of pixel electrodes and the data line, arranged parallel to the plurality of pixel electrodes, and connected to at least one of the common wiring and the storage line.

8. The thin-film transistor array panel of claim 7, further comprising a second connection electrode which connects the plurality of common electrodes to the storage line, wherein the shield electrode is connected to at least one of the plurality of common electrodes and the storage line by the second connection electrode.

9. The thin-film transistor array panel of claim 1, wherein the plurality of common electrodes and the plurality of pixel electrodes at least partially overlap the common wiring and the storage line.

10. The thin-film transistor array panel of claim 1, further comprising:
a thin-film transistor which comprises a gate electrode connected to the gate line, a source electrode connected to the data line, and a drain electrode connected to a corresponding pixel electrode of the plurality of the pixel electrodes; and
a first connection electrode which connects the pixel electrode to the drain electrode,
wherein the common wiring overlaps at least one of the first connection electrode and the pixel electrode.

11. The thin-film transistor array panel of claim 1, further comprising a first passivation layer which is formed on regions of the insulating substrate and the gate insulating film that do not overlap the data line, the plurality of common electrodes and the plurality of pixel electrodes.

12. The thin-film transistor array panel of claim 11, further comprising a second passivation layer formed on the data line, the plurality of common electrodes, the plurality of pixel electrodes and the first passivation layer.

13. A method of fabricating a thin-film transistor array panel, the method comprising:
disposing a gate line and common wiring, which extends parallel to the gate line, on an insulating substrate;
disposing a gate insulating film and a semiconductor layer on the gate line and the common wiring;
forming contact holes which penetrate through the gate insulating film and the semiconductor layer disposed on the common wiring; and
disposing a plurality of common electrodes which are connected to the common wiring by the contact holes and are arranged parallel to each other, a plurality of pixel electrodes which are arranged parallel to the common electrodes, and a data line which crosses the gate line.

14. The method of claim 13, wherein in the disposing of the plurality of common electrodes, the plurality of pixel electrodes and the data line, an etching process is performed using a photoresist pattern, which is formed on a data line formation region, a common electrode formation region and a pixel electrode formation region, as an etching mask.

15. The method of claim 14, wherein the forming of the plurality of common electrodes, the plurality of pixel electrodes and the data line comprises depositing a conductive material for disposing the data line on the insulating substrate and wet-etching the deposited conductive material.

16. The method of claim 14, further comprising disposing a first passivation layer on regions of the insulating substrate and the gate insulating film which do not overlap the plurality of common electrodes, the plurality of pixel electrodes and the data line.

17. The method of claim 16, wherein the disposing the first passivation layer comprises depositing a material for disposing the first passivation layer on the insulating substrate having the photoresist pattern and removing the photoresist pattern by using a lift-off process.

18. The method of claim 16, further comprising disposing a second passivation layer on the plurality of common electrodes, the plurality of pixel electrodes, the data line and the first passivation layer.

19. The method of claim 18, wherein the gate line further comprises a gate pad at an end thereof, and the method further comprises etching the second passivation layer to expose the gate pad.

20. The method of claim 13, further comprising:
disposing a storage line which extends parallel to the gate line; and
disposing a storage electrode which is connected to the storage line and overlaps the plurality of pixel electrodes.

21. The method of claim 20, further comprising disposing a connection electrode which connects the plurality of common electrodes to the storage line.

22. The method of claim 21, wherein at least part of the connection electrode does not overlap the gate insulating film and the semiconductor layer.

23. The method of claim 22, further comprising forming a shield electrode which is interposed between the data line and at least one of the plurality of pixel electrodes and the plurality of common electrodes, arranged parallel to the plurality of pixel electrodes, and connected to the connection electrode.

24. The method of claim 13, further comprising disposing a shield electrode which is interposed between the data line and at least one of the plurality of pixel electrodes and the plurality of common electrodes, arranged parallel to the plurality of pixel electrodes, and connected to at least one of the plurality of common electrodes and the plurality of pixel electrodes.
